(19) United States
(12) Patent Application Publication
(10) Pub. No.: US 2023/0096780 A1
(43) Pub. Date: Mar. 30, 2023

(54) DETECTING CIRCUIT AND A DETECTING SYSTEM OF A BACK-UP ENERGY-STORING SYSTEM AND RELATED DETECTING METHOD THEREOF

(71) Applicant: Chongqing Diange Technology (Group) Co.Ltd., Chongqing (CN)

(72) Inventors: Xiaoming Gong, Chongqing (CN); Liang Tan, Chongqing (CN); Zhicheng Wei, Chongqing (CN); Jin Yang, Chongqing (CN); Liang Wu, Chongqing (CN)

(21) Appl. No.: 17/704,386

(22) Filed: Mar. 25, 2022

(30) Foreign Application Priority Data
Sep. 24, 2021 (CN) 202111120179.0

(51) Int. Cl. H02J 7/00

(52) U.S. Cl. CPC H02J 7/0047; H02J 7/0036

(57) ABSTRACT

The present disclosure provides a detecting circuit and a detecting system of a back-up energy-storing system and related detecting method thereof. The detecting circuit comprises a battery, insulation resistors, resistors, voltage sources, and switches. The detecting system comprises an detecting circuit, voltage acquisition chips and a MCU. By calculating the resistance values of the insulation resistors, and detecting the insulativity between the positive pole and negative pole of the battery and the housing of the back-up energy-storing system, Circuit design of the detecting system of the present disclosure is simple and detecting accuracy of the detecting system of the present disclosure is high. It is convenient for an user to judge the safety of the detecting system.

### CROSS-REFERENCE TO RELATED APPLICATIONS

This application claims a priority of the following Chinese Patent Application: CN 202111120179.0 filed on Sep. 24, 2021, the disclosures of which are incorporated herein in their entirety by reference.

### BACKGROUND

### Technical Field

The present disclosure relates to a detecting circuit, and more particularly to a detecting circuit and a detecting system of a back-up energy-storing system and related detecting method thereof.

### Related Art

In the prior art, as shown in FIG. 1, the back-up energy-storing system that is the electric vehicle emergency energy-storing system, mainly includes energy-storing modules, charging modules, discharging modules, charging interfaces, discharging interfaces and other modules. The energy-storing module can be a battery or other energy-storing device for storing energy. The charging module and the discharging module is generally a direct current or an alternating current power supply, which can provide the type of the required power source. The discharging module can be the module of direct current to direct current or direct current to alternating current. The charging interface and the discharging interface can be an alternating current socket, a direct current socket or an electric vehicle charging interface and so on to connect with an external charging and discharging equipment. Other modules include some extended modules, which can be communication modules, display modules, etc.

In addition, insulation detection of the battery system within the back-up energy-storing system is required. The method of insulation detection is as follows: a balanced bridge detecting method, a low frequency signal method, and a differential current detection principle method.

As shown in FIG. 2, the principle of the balanced bridge detecting method is that the positive and negative poles of the busbar is electrically connected to a resistance bridge, so that the resistance bridge are formed a resistance bridge with the insulation resistors R+, R− between the positive and negative poles of the power source and the ground. The resistance bridge is to use the ground as the middle end of the bridge, and a relay between the two resistance bridges is connected to judge whether there is an insulation fault. However, when the positive and negative busbar insulation resistance of the direct current system to ground decreases equally, the bridge is still balanced, and the electric circuit cannot issue an alert signal through the relay.

As shown in FIG. 3, the principle of the low frequency signal detection method is to input a low frequency voltage signal regularly between the positive and negative busbars of the direct current system and the ground, and use the current transformer connected to the branch to detect the mutual inductance current in each branch, so that the flow direction of the input voltage signal can be judged, and the fault branch can be found. However, the electric circuit requires a large dynamic range and high measurement accuracy for the current transformer which is difficult to achieve in prior art. The electric circuit will still interfere with the direct current system. Also, the range of using the electric circuit is quite limited.

And the principle of the differential current detection method is to install a direct current sensor on the direct current branch of the system, so that the leakage current value of the direct current system branch can be directly detected through the direct current sensor to judge whether there is a ground fault. However, the method still has technical shortcomings in practice, and the safety performance is limited.

### SUMMARY

A number of embodiments of the present disclosure are described herein in summary. However, the vocabulary expression of the present disclosure is only used to describe some embodiments (whether or not already in the claims) disclosed in this specification, rather than a complete description of all possible embodiments. Some embodiments described above as various features or aspects of the present disclosure may be combined in different ways to form a detecting circuit and a detecting system of a back-up energy-storing system and related detecting method thereof.

In order to solve the problems existing in the prior art, the present disclosure provides a detecting circuit of a back-up energy-storing system comprising a battery BT1, a insulation resistor R+, a insulation resistor R−, resistors R1-R6, switches K1-K4 and voltage sources 1-2.

The positive pole of the battery BT1 is electrically connected to one end of the insulation resistor R+ and one end of the switch K1. The negative pole of the battery BT1 is electrically connected to one end of the insulation resistor R− and one end of the switch K2. And the other end of the insulation resistor R+ and the other end of the insulation resistor R− are electrically connected to the ground GND.

The other end of the switch K1 is electrically connected to one end of the resistor R1 and one end of the double-pole switch K3. The other end of the switch K2 is electrically connected to one end of the resistor R2 and one end of the double-pole switch K4. And the other end of the resistor R1 and the other end of the resistor R2 are electrically connected to the ground GND.

The two end of the double-pole switch K3 is electrically connected to one end of the resistor R5. The two end of the double-pole switch K4 is electrically connected to one end of the resistor R6. And the other end of the resistor R5 and the other end of the resistor R6 are electrically connected to the ground GND.

The common end of the double-pole switch K3 electrically is connected to the positive pole of the voltage source 1 through the resistor R3. The common end of the double-pole switch K4 is electrically connected to the negative pole of the voltage supply 2. The positive pole of the voltage source 2 is electrically connected to one end of the resistor R4. And the negative pole of the voltage source 1 and the other end of the resistor R4 are electrically connected to the ground GND.

In order to solve the problems existing in the prior art, the present disclosure provides a detecting system of a back-up energy-storing system, comprising the detecting circuit described above, voltage acquisition chips 1, 2, 3, 4 and a microcontroller unit (MCU).

The two ends of the resistor R3, R4, R5, R6 are electrically connected to the input end of the voltage acquisition chips 1, 3, 2, 4. And the output end of the voltage acquisition chips 1, 2, 3, 4 are electrically connected to the MCU.

The voltage acquisition chips 1, 3, 2, 4 are used to collect voltage values at both ends of the resistor R3, R4, R5, R6, and transmit data of the voltage values to the MCU, respectively.

The MCU is used to control states of the switches K1-K4, and calculate resistance values of the insulation resistor R+ and the insulation resistor R− to issue an alert when at least on of the two resistance values are below a predetermined value.

Preferably, the resistors R5, R6 are precision resistors with known resistance values.

Preferably, the model of the voltage acquisition chips 1, 2, 3, 4 is INA181A1IDBVR.

Preferably, the MCU is also connected to a buzzer and/or a LED for issuing the alert.

In order to solve the problems existing in the prior art, the present disclosure provides a detecting method of a back-up energy-storing system, by the detecting system of a back-up energy-storing system described above, calculating the resistance value of the insulation resistor R+ to detect insulativity between the positive pole of the battery BT1 and a housing of the back-up energy-storing system, and comprising the following steps:

A1: disconnecting the switches K1, K2 so that the voltage source 2 does not work and the voltage source 1 works, and placing the double-pole switch K3 at the 2 end; then measuring a voltage value V3 of two ends of the resistor R3 and a voltage value V5 of two ends of the resistor R5, and calculating a resistance value of the resistor R3, the formula is as below:

$$R 3 = \frac{V 3}{\frac{V 5}{R 5}}$$

A2: placing the double-pole switch K3 at the 1 end, and then measuring the voltage value V3 of two ends of the resistor R3, and calculating the resistance value of the resistor R1, the formula is as below:

$$R 1 = \frac{V voltage source 1 - V 3}{\frac{V 3}{R 3}}$$

A3: turning on the switch K1, and then measuring the voltage V3 of two ends of the resistor R3, at this time the insulation resistor R+ and R1 are in parallel connection and getting a parallel resistor Rₜ+ of the two resistors R+ and R1, and calculating the resistance value of the parallel resistor Rₜ+, the formula is as below:

$${R}_{t} + = \frac{V voltage source 1 - V 3}{\frac{V 3}{R 3}}$$

A4: calculating the resistance value of the insulation resistor R+, the formula is as below:

the resistance value of the insulation resistor

$$R + = \frac{{R}_{t} + \times R 1}{R 1 - {R}_{t} +}$$

Preferably, the MCU will issue the alert, when the calculated resistance value of the insulation resistor R+ is lower than the predetermined value.

In order to solve the problems existing in the prior art, the present disclosure provides a detecting method of a back-up energy-storing system, wherein by the detecting system of a back-up energy-storing system described above, calculating the resistance value of the insulation resistor R−, to detect the insulativity between the negative pole of the battery BT1 and a housing of the back-up energy-storing system, comprising the following steps:

B1: disconnecting the switches K1, K2 so that the voltage source 1 does not work and the voltage source 2 works, and placing the double-pole switch K4 at the 2 end; then measuring a voltage value V4 of two ends of the resistor R4, calculating an electric current I6 by a voltage value of two ends of the resistor R6, and calculating a resistance value of the resistor R4, the formula is as below:

$$R 4 = \frac{V 4}{\frac{V 6}{R 6}}$$

B2: placing the double-pole switch K4 at the 1 end, and then measuring the voltage value V4 of two ends of the resistor R4, and calculating a resistance value of the resistor R2 the formula is as below:

$$R 2 = \frac{V voltage source 2 - V 4}{\frac{V 4}{R 4}}$$

B3: turning on the switch K2, and then measuring the voltage V4 of two ends of the resistor R4, at this time the insulation resistor R− and R2 are in parallel connection and getting a parallel resistor Rₜ− of the two resistor R− and R2, and calculating the resistance value of the parallel resistor Rₜ−, the formula is as below:

$${R}_{t} - = \frac{V voltage source 2 - V 4}{\frac{V 4}{R 4}}$$

B4, calculating the resistance value of the insulation resistor R−, the formula is as below:

the resistance value of the insulation resistor

$$R - = \frac{{R}_{t} - \times R 2}{R 2 - {R}_{t} -}$$

Preferably, the MCU will issue the alert, when the calculated resistance value of the insulation resistor R− is lower than the predetermined value.

In summary, the present disclosure can correct the resistance value of the back-up energy-storing system to prevent the aging resistance value from changing. It can also detect decreases of the insulation resistance of the positive and negative poles of the battery.

Compared with the prior art, the present disclosure has the following advantages:

1. The detecting system of the present disclosure can self-correct the resistance value, for example, each time the detecting system will calculate the resistance values of the resistors R1-R4 according to the voltage values of the current-time measurement, rather than the original resistance values of the resistors. Circuit design of the detecting system of the present disclosure is simple and detecting accuracy of the detecting system of the present disclosure is high.

2. The detecting method of the present disclosure, by calculating the resistance value of the insulation resistor R+ or the insulation resistor R− to detect the insulativity between the positive pole of the battery BT1 and a housing of the back-up energy-storing system. Detecting steps are simple, detecting time is short and response is timely.

3. The MCU of the detecting method of the present disclosure will issue the alert for an user to judge the safety of the detecting system, when the calculated resistance value of the insulation resistor R+ or the insulation resistor R− is lower than the predetermined value.

### BRIEF DESCRIPTION OF THE DRAWINGS

In order to more clearly explain the embodiment of the present disclosure or the technical scheme in the prior art, the following will briefly introduce the attached drawings that need to be used in the embodiment. It is obvious that the attached drawings in the following description are only some embodiments of the present disclosure. For ordinary technicians in the art, without paying creative labor, other drawings can also be obtained from these drawings.

FIG. 1 illustrates a circuit schematic diagram of a electric vehicle emergency energy-storing system in the prior art;

FIG. 2 illustrates a circuit schematic diagram of a balanced bridge detecting method in the prior art;

FIG. 3 illustrates a circuit schematic diagram of a low frequency signal detecting method in the prior art;

FIG. 4 illustrates an detecting circuit diagram of a back-up energy-storing system of the present insulation;

FIG. 5 illustrates a flowchart of the present insulation calculating the resistance value of the insulation resistor R+; and

FIG. 6 illustrates a flowchart of the present insulation calculating the resistance value of the insulation resistor R−.

### DETAILED DESCRIPTION

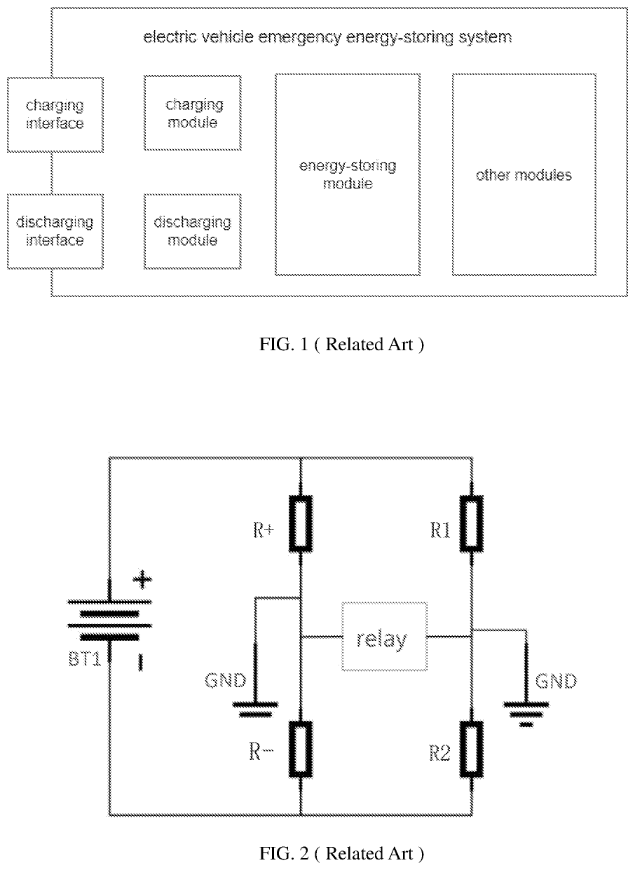

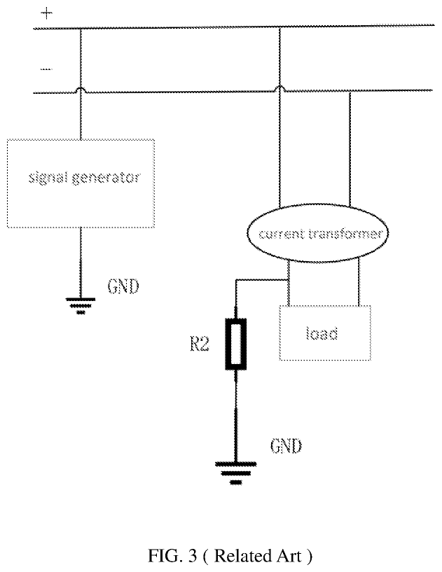

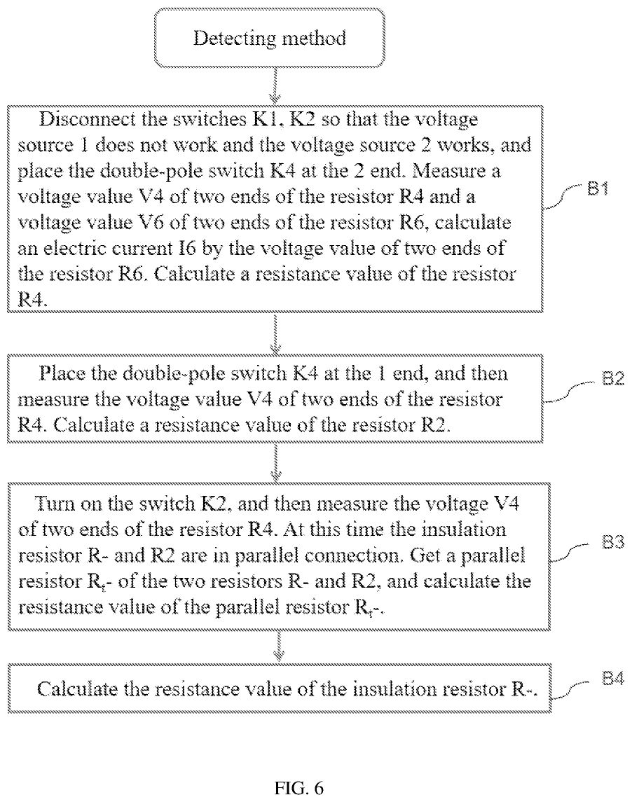

The present disclosure will be described below in detail in combination with preferred embodiments and attached drawings as shown in FIG. 1 to FIG. 6.

The present disclosure provides a detecting circuit and a detecting system of a back-up energy-storing system and related detecting method thereof.

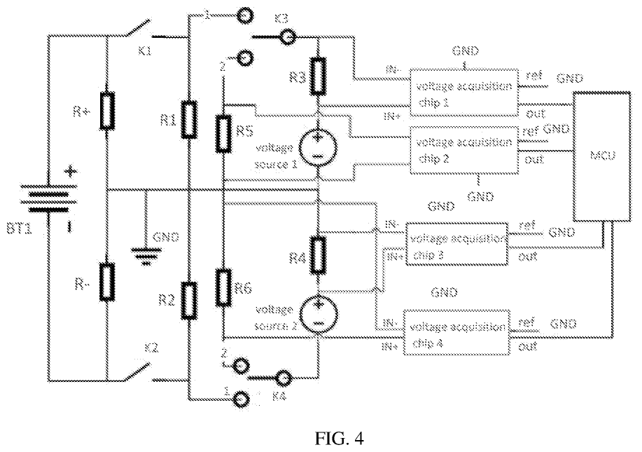

As shown in FIG. 4, the detecting circuit comprises a battery BT1, two insulation resistors R+, R−, six resistors R1-R6, two voltage sources 1-2, and four switches K1-K4. The insulation resistance R+ is the equivalent resistance between the positive pole of the battery BT1 and the housing of the back-up energy-storing system. Similarly, the insulation resistor R− is the equivalent resistance between the negative pole of the battery BT1 and the housing of the back-up energy-storing system.

The electrical connection of the detecting circuit is as below:

The positive pole of the battery BT1 is electrically connected to one end of the insulation resistor R+ and one end of the switch K1. The negative pole of the battery BT1 is electrically connected to one end of the insulation resistor R− and one end of the switch K2. And the other end of the insulation resistor R+ and the other end of the insulation resistor R− are electrically connected to the ground GND.

The other end of the switch K1 is electrically connected to one end of the resistor R1 and one end of the double-pole switch K3. The other end of the switch K2 is electrically connected to one end of the resistor R2 and one end of the double-pole switch K4. And the other end of the resistor R1 and the other end of the resistor R2 are electrically connected to the ground GND.

The two end of the double-pole switch K3 is electrically connected to one end of the resistor R5. The two end of the double-pole switch K4 is electrically connected to one end of the resistor R6. And the other end of the resistor R5 and the other end of the resistor R6 are electrically connected to the ground GND.

The common end of the double-pole switch K3 electrically is connected to the positive pole of the voltage source 1 through the resistor R3. The common end of the double-pole switch K4 is electrically connected to the negative pole of the voltage supply 2. The positive pole of the voltage source 2 is electrically connected to one end of the resistor R4. And the negative pole of the voltage source 1 and the other end of the resistor R4 are electrically connected to the ground GND.

As shown in FIG. 4, a detecting system of the back-up energy-storing system of the present disclosure comprises the detecting circuit described above, four voltage acquisition chips 1, 2, 3, 4, a microcontroller unit (MCU), and a buzzer and/or a LED (not shown in FIG. 4).

The electrical connection of the detecting system is as below: the two ends of the resistor R3, R4, R5, R6 are electrically connected to the input end of the voltage acquisition chips 1, 3, 2, 4. And the output end of the voltage acquisition chips 1, 2, 3, 4 are electrically connected to the MCU. The MCU is connected to the buzzer and/or the LED for issuing the alert.

In this embodiment, the resistors R5, R6 are precision resistors with known resistance values, enabling the detecting method of the present disclosure to calculate. The model of the voltage acquisition chips 1, 2, 3, 4 is INA181A1IDBVR. The voltage acquisition chips 1, 3, 2, 4 are used to collect voltage values at both ends of the resistor R3, R4, R5, R6, and transmit data of the voltage values to the MCU, respectively.

The working principle of the detecting circuit and the detecting method is as below: the MCU is used to control states of the switches K1-K4, receive the voltage values of the resistors R3, R4, R5, R6 transmitted by the voltage acquisition chips 1, 2, 3, 4 and calculate resistance values of the insulation resistor R+ and the insulation resistor R− to issue an alert when at least on of the two resistance values are below a predetermined value.

That is, to calculate resistance values of the resistors R3, R4 by detecting the electric current values of the precision resistor R5 and the precision resistor R6. To detect the reliability of the insulativity between the positive pole of the battery BT1 and the housing of the back-up energy-storing system by detecting the voltage value of the resistor R3. To detect the reliability of the insulativity between the negative pole of the battery BT1 and the housing of the back-up energy-storing system by detecting the voltage value of the resistor R4. In addition, the MCU will control the buzzer and/or the LED to issue the alert, when the calculated resistance value of the insulation resistor R+ and the insulation resistor R− is lower than the predetermined value.

The insulation detecting method of the insulation detecting circuit and the insulation detecting system of the present invention described above is as below.

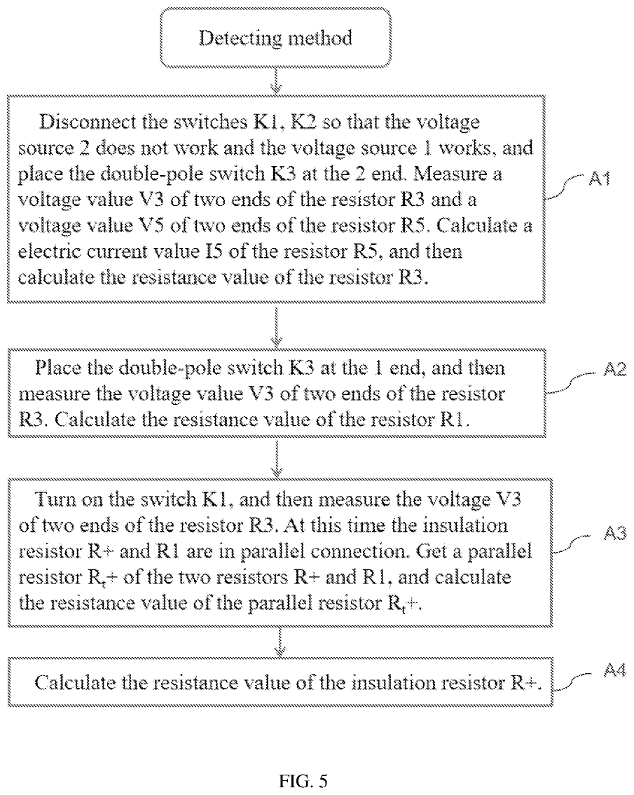

To detect the insulativity between the positive pole of the battery BT1 and the housing of the back-up energy-storing system, so as to calculate the resistance value of the insulation resistor R+. The flowchart of the detecting method is shown in FIG. 5:

A1: To disconnect the switches K1, K2 and place the double-pole switch K3 at the 2 end so that the voltage source 2 does not work and the voltage source 1 works. Then, to measure a voltage value V3 of two ends of the resistor R3 and a voltage value V5 of two ends of the resistor R5. Firstly, to calculate a electric current value I5 of the resistor R5, the formula is as below:

$$I 5 = \frac{V 5}{R 5}$$

then, to calculate the resistance value of the resistor R3, the formula is as below:

$$R 3 = \frac{V 3}{I 5}$$

A2: To place the double-pole switch K3 at the 1 end, and then to measure the voltage value V3 of two ends of the resistor R3, and to calculate the resistance value of the resistor R1. The formula is as below:

$$R 1 = \frac{V voltage source 1 - V 3}{\frac{V 3}{R 3}}$$

A3: To turn on the switch K1, and then to measure the voltage V3 of two ends of the resistor R3. At this time the insulation resistor R+ and R1 are in parallel connection, and a parallel resistor Rₜ+ of the two resistors R+ and R1 is obtained. Then, to calculate the resistance value of the parallel resistor Rₜ+, the formula is as below:

$${R}_{t} + = \frac{V voltage source 1 - V 3}{\frac{V 3}{R 3}}$$

A4: To calculate the resistance value of the insulation resistor R+, the formula is as below:
the resistance value of the insulation resistor

$$R + = \frac{{R}_{t} + \times R 1}{R 1 - {R}_{t} +}$$

The MCU will issue the alert, when the calculated resistance value of the insulation resistor R+ is lower than the predetermined value.

To detect the insulativity between the positive pole of the battery BT1 and the housing of the back-up energy-storing system, so as to calculate the resistance value of the insulation resistor R+. The flowchart of the detecting method is shown in FIG. 5:

B1: To disconnect the switches K1, K2 and place the double-pole switch K4 at the 2 end so that the voltage source 1 does not work and the voltage source 2 works. Then, to measure a voltage value V4 of two ends of the resistor R4, to calculate an electric current I6 by a voltage value of two ends of the resistor R6, and to calculate a resistance value of the resistor R4, the formula is as below:

$$R 4 = \frac{V 4}{\frac{V 6}{R 6}}$$

B2: To place the double-pole switch K4 at the 1 end, and then to measure the voltage value V4 of two ends of the resistor R4, and to calculate a resistance value of the resistor R2 the formula is as below:

$$R 2 = \frac{V voltage source 2 - V 4}{\frac{V 4}{R 4}}$$

B3: To turn on the switch K2, and then to measure the voltage V4 of two ends of the resistor R4. At this time the insulation resistor R− and R2 are in parallel connection, and a parallel resistor Rₜ− of the two resistor R− and R2 is obtained. Then, to calculate the resistance value of the parallel resistor Rₜ−, the formula is as below:

$${R}_{t} - = \frac{V voltage source 2 - V 4}{\frac{V 4}{R 4}}$$

B4: To calculate the resistance value of the insulation resistor R−, the formula is as below:
the resistance value of the insulation resistor

$$R - = \frac{{R}_{t} - \times R 2}{R 2 - {R}_{t} -}$$

The MCU will issue the alert, when the calculated resistance value of the insulation resistor R− is lower than the predetermined value.

In summary, the present disclosure can correct the resistance value of the back-up energy-storing system to prevent the aging resistance value from changing. It can also detect decreases of the insulation resistance of the positive and negative poles of the battery.

Compared with the prior art, the present disclosure has the following advantages:

1. The detecting system of the present disclosure can self-correct the resistance value, for example, each time the detecting system will calculate the resistance values of the resistors R1-R4 according to the voltage values of the current-time measurement, rather than the original resistance values of the resistors. Circuit design of the detecting system of the present disclosure is simple and detecting accuracy of the detecting system of the present disclosure is high.

2. The detecting method of the present disclosure, by calculating the resistance value of the insulation resistor R+ or the insulation resistor R− to detect the insulativity between the positive pole of the battery BT1 and a housing of the back-up energy-storing system. Detecting steps are simple, detecting time is short and response is timely.

3. The MCU of the detecting method of the present disclosure will issue the alert for an user to judge the safety of the detecting system, when the calculated resistance value of the insulation resistor R+ or the insulation resistor R− is lower than the predetermined value.

It should be noted that the present disclosure is not limited to the above embodiments. According to the creative spirit of the present disclosure, those skilled in the art can also make other modifications, which should not be interpreted as limiting the scope of the present disclosure. It should be noted that all modifications and substitutions equivalent to the embodiment should be included in the scope of the present disclosure. Therefore, the scope of protection of the present disclosure shall be subject to the scope defined in the claims.

What is claimed is:

1. A detecting circuit of a back-up energy-storing system, comprising:
a battery BT1, a insulation resistor R+, a insulation resistor R−, resistors R1-R6, switches K1-K4 and voltage sources 1-2;
wherein the positive pole of the battery BT1 is electrically connected to one end of the insulation resistor R+ and one end of the switch K1, the negative pole of the battery BT1 is electrically connected to one end of the insulation resistor R− and one end of the switch K2, and the other end of the insulation resistor R+ and the other end of the insulation resistor R− are electrically connected to the ground GND;
wherein the other end of the switch K1 is electrically connected to one end of the resistor R1 and one end of the double-pole switch K3, the other end of the switch K2 is electrically connected to one end of the resistor R2 and one end of the double-pole switch K4, and the other end of the resistor R1 and the other end of the resistor R2 are electrically connected to the ground GND;
wherein the two end of the double-pole switch K3 is electrically connected to one end of the resistor R5, the two end of the double-pole switch K4 is electrically connected to one end of the resistor R6, and the other end of the resistor R5 and the other end of the resistor R6 are electrically connected to the ground GND;
wherein the common end of the double-pole switch K3 electrically is connected to the positive pole of the voltage source 1 through the resistor R3, the common end of the double-pole switch K4 is electrically connected to the negative pole of the voltage supply 2, the positive pole of the voltage source 2 is electrically connected to one end of the resistor R4, and the negative pole of the voltage source 1 and the other end of the resistor R4 are electrically connected to the ground GND.

2. A detecting system of a back-up energy-storing system, comprising the detecting circuit of claim 1, voltage acquisition chips 1, 2, 3, 4 and a microcontroller unit (MCU);
wherein the two ends of the resistor R3, R4, R5, R6 are electrically connected to the input end of the voltage acquisition chips 1, 3, 2, 4, and the output end of the voltage acquisition chips 1, 2, 3, 4 are electrically connected to the MCU;
wherein the voltage acquisition chips 1, 3, 2, 4 are used to collect voltage values at both ends of the resistor R3, R4, R5, R6, and transmit data of the voltage values to the MCU, respectively;
wherein the MCU is used to control states of the switches K1-K4, and calculate resistance values of the insulation resistor R+ and the insulation resistor R− to issue an alert when at least on of the two resistance values are below a predetermined value.

3. The detecting system of a back-up energy-storing system of claim 2, wherein the resistors R5, R6 are precision resistors with known resistance values.

4. The detecting system of a back-up energy-storing system of claim 2, wherein the model of the voltage acquisition chips 1, 2, 3, 4 is INA181A1IDBVR.

5. The detecting system of a back-up energy-storing system of claim 2, wherein the MCU is also connected to a buzzer and/or a LED for issuing the alert.

6. A detecting method of a back-up energy-storing system, wherein by the detecting system of a back-up energy-storing system of claim 2, calculating the resistance value of the insulation resistor R+, to detect insulativity between the positive pole of the battery BT1 and a housing of the back-up energy-storing system, comprising the following steps:
A1: disconnecting the switches K1, K2 so that the voltage source 2 does not work and the voltage source 1 works, and placing the double-pole switch K3 at the 2 end; then measuring a voltage value V3 of two ends of the resistor R3 and a voltage value V5 of two ends of the resistor R5, and calculating a resistance value of the resistor R3, the formula is as below:
$$R 3 = \frac{V 3}{\frac{V 5}{R 5}}$$
A2: placing the double-pole switch K3 at the 1 end, and then measuring the voltage value V3 of two ends of the resistor R3, and calculating the resistance value of the resistor R1, the formula is as below:
$$R 1 = \frac{V voltage source 1 - V 3}{\frac{V 3}{R 3}}$$
A3: turning on the switch K1, and then measuring the voltage V3 of two ends of the resistor R3, at this time the insulation resistor R+ and R1 are in parallel connection and getting a parallel resistor Rₜ+ of the two resistors R+ and R1, and calculating the resistance value of the parallel resistor Rₜ+, the formula is as below:
$${R}_{t} + = \frac{V voltage source 1 - V 3}{\frac{V 3}{R 3}}$$
A4: calculating the resistance value of the insulation resistor R+, the formula is as below:
the resistance value of the insulation resistor
$$R + = \frac{{R}_{t} + \times R 1}{R 1 - {R}_{t} +}$$

7. The detecting method of a back-up energy-storing system of claim 6, wherein the MCU will issue the alert, when the calculated resistance value of the insulation resistor R+ is lower than the predetermined value.

8. A detecting method of a back-up energy-storing system, wherein by the detecting system of a back-up energy-storing system of claim 2, calculating the resistance value of the insulation resistor R−, to detect the insulativity between the negative pole of the battery BT1 and a housing of the back-up energy-storing system, comprising the following steps:
B1: disconnecting the switches K1, K2 so that the voltage source 1 does not work and the voltage source 2 works, and placing the double-pole switch K4 at the 2 end; then measuring a voltage value V4 of two ends of the resistor R4, calculating an electric current I6 by a voltage value of two ends of the resistor R6, and calculating a resistance value of the resistor R4, the formula is as below:
$$R 4 = \frac{V 4}{\frac{V 6}{R 6}}$$
B2: placing the double-pole switch K4 at the 1 end, and then measuring the voltage value V4 of two ends of the resistor R4, and calculating a resistance value of the resistor R2 the formula is as below:
$$R 2 = \frac{V voltage source 2 - V 4}{\frac{V 4}{R 4}}$$
B3: turning on the switch K2, and then measuring the voltage V4 of two ends of the resistor R4, at this time the insulation resistor R− and R2 are in parallel connection and getting a parallel resistor Rₜ− of the two resistor R− and R2, and calculating the resistance value of the parallel resistor Rₜ−, the formula is as below:
$${R}_{t} - = \frac{V voltage source 2 - V 4}{\frac{V 4}{R 4}}$$
B4, calculating the resistance value of the insulation resistor R−, the formula is as below:
the resistance value of the insulation resistor
$$R - = \frac{{R}_{t} - \times R 2}{R 2 - {R}_{t} -}$$

9. The detecting method of a back-up energy-storing system of claim 8, wherein the MCU will issue the alert, when the calculated resistance value of the insulation resistor R− is lower than the predetermined value.
